(19) United States
(12) Patent Application Publication
(10) Pub. No.: US 2007/0015006 A1
(43) Pub. Date: Jan. 18, 2007

(54) White organic light emitting diode

(76) Inventors: Jun Yeob Lee, Seongnam (KR); Min Seung Chun, Yongin (KR)

Correspondence Address: CHRISTIE, PARKER & HALE, LLP, PO BOX 7068, PASADENA, CA, 91109-7068, US

(21) Appl. No.: 11/486,762

(22) Filed: Jul. 13, 2006

(30) Foreign Application Priority Data
Jul. 15, 2005 (KR) 10-2005-0064460

(51) Int. Cl. H01L 51/54; H05B 33/14

(52) U.S. Cl. 428/690; 428/917; 313/504; 313/506; 257/E51.044

(57) ABSTRACT

A white organic light emitting diode (OLED) includes an emission layer between two electrodes. The emission layer comprises two or more kinds of compounds for the host and two or more kinds of compounds for the dopant that facilitate production of a white color. Among the two or more kinds of compounds for the host, at least one is a hole transporting material and the other is an electron transporting material. The white OLED has improved stability which increases its efficiency and life.

### CROSS-REFERENCE TO RELATED APPLICATIONS

This application claims priority to and the benefit of Korean Patent Application No. 2004-64460, filed on Jul. 15, 2005, in the Korean Intellectual Property Office, the entire content of which is incorporated herein by reference.

### BACKGROUND

1. Field of the Invention

The present invention relates to a white organic light emitting diode (OLED) in which the structure of the emission layer is improved, thereby increasing the life of the white OLED.

2. Discussion of Related Art

In general, an organic light emitting diode (OLED) includes a substrate, an anode, an organic layer including an emission layer, and a cathode. The OLED is a spontaneous emission display that generates light by a combination of electrons and holes in the emission layer, realizing a light and thin information display device that is driven at a low voltage, displays images with high picture quality, has high response speed, and has a wide viewing angle. Such OLEDs are applied to high quality information display devices as well as to mobile telephones.

The OLEDs that effectively generate white light can be widely used as the backlights of LCD displays, the internal lights of vehicles, and the lights in offices, and can be used as color flat panel displays when filters of the three primary colors, red, blue, and green, are assembled to manufacture the OLEDs.

The white OLEDs can be obtained by various methods, but are typically manufactured by two main methods. According to the first method, the emission layer is composed of multiple layers that emit red, blue, and green. Using this method, it is not easy to form the multiple layers, the thickness of the thin film that emits white light must be obtained through trial and error without regulations, the color of light significantly changes in accordance with voltage, and the stability of the white OLED deteriorates, thereby producing a white OLED with a very short life. According to the second method, emission host material is doped or mixed with an organic light emitting pigment. The processes of this method are simpler than the processes of the method in which the emission layer is composed of multiple layers. However, according to the second method, the thin film that emits the white light is also obtained through trial and error. Also, since the white color can only be controlled by controlling the doping concentration, the life of the white OLED is determined by the doping concentration.

Therefore, white OLEDs having excellent emission efficiency and long life are still required.

### SUMMARY OF THE INVENTION

In one embodiment, the invention provides a white organic light emitting diode (OLED) with improved emission efficiency and a longer lifespan wherein at least one of the materials that has hole transporting properties and at least one material that has electron transporting properties are used in an emission layer.

In an embodiment of the present invention, a white organic light emitting diode comprising an emission layer between two electrodes is provided, wherein the emission layer comprises two or more types of compounds for the host and two or more kinds of compounds for the dopant that produce white color. Among the two or more kinds of compounds for the host, at least one is a hole transporting material, and the other is an electron transporting material.

### BRIEF DESCRIPTION OF THE DRAWINGS

These and/or other objects and advantages of the invention will become apparent and more readily appreciated from the following description of the embodiments, taken in conjunction with the accompanying drawings of which:

FIG. 1 schematically illustrates the structure of a white organic light emitting diode (OLED) according to one embodiment of the invention; and

FIG. 2 is a graph that illustrates the emission characteristics of a white OLED according to an embodiment of the invention.

### DETAILED DESCRIPTION OF PREFERRED EMBODIMENTS

Hereinafter, embodiments of the present invention will be described with reference to the accompanying drawings.

In one embodiment, a white OLED according to the invention includes an emission layer between a first electrode (anode) and a second electrode (cathode) where the emission layer includes two or more kinds of compounds for the host and two or more kinds of compounds for the dopant that produce white color wherein the host comprises at least one hole transporting material and at least one electron transporting material.

In another embodiment for a white OLED according to the invention, a hole injecting layer and/or a hole transporting layer may be sequentially stacked between the first electrode and the emission layer, and a hole blocking layer, an electron transporting layer and/or an electron injecting layer may be sequentially stacked between the emission layer and the second electrode. In a further embodiment, an intermediate layer may be inserted in order to improve interlayer interface characteristics.

In one embodiment, among the compounds for the host that constitute the emission layer, compounds that include a carbazole unit may be used as the hole transporting material. In another embodiment, the host comprises at least one compound selected from the group consisting of 1,3,5-triscarbazolylbenzene; 4,4′-biscarbazolylbiphenyl; polyvinylcarbazole; m-biscarbazolybilphenyl; 4,4′-biscarbazolyl-2,2′-dimethylbiphenyl; 4,4′,4″-tri(N-carbazolyl)triphenylamine; 1,3,5-tris(2-carbazolylphenyl)benzene; 1,3,5-tris(2-carbazoleyl-5-methoxyphenyl)benzene; bi(4-carbazolylphenyl)silane, and combinations thereof. In an embodiment, the compounds for the host comprise organic metal based materials such as aluminum, zinc, beryllium, or potassium based materials; materials including oxadiazol units; materials including triazine units; materials including triazol units; and materials including spiro fluorene units, may be used as the electron transporting material. In one embodiment, at least one material selected from the group consisting of bis(8-hydroxyquinolato)biphenoxy aluminum; bis(8-hydroxyquinolato)phenoxy aluminum; bis(2-methyl-8-hydroxyquinolato)biphenoxy aluminum; bis(2-methyl-8-hydroxyquinolato)phenoxy aluminum; bis(2-(2-hydroxyphenyl)quinolato)zinc; 2-(4-biphenylyl)-5-(4-tert-butylphenyl)-1,3,4-oxadiazol; 2,9-dimethyl-4,7-diphenyl-1,10-phenanthroline(BCP); 2,4,6-tris(diarylamino)-1,3,5-triazine; 3-phenyl-4-(1′-naphthyl)-5-phenyl-1,2,4-triazole, and combinations thereof is used.

In an embodiment, the hole transporting material in the amount of 10 to 90wt % with respect to the total weight of the compounds for the host, is used. In another embodiment, the electron transporting material in the amount of 10 to 90wt % with respect to the total weight of the compounds for the host, is used. When the weights of the hole transporting material and the electron transporting material deviate from the above-described ranges, the hole transporting material and the electron transporting material show the characteristics of the host, but their characteristics are not improved.

In an embodiment, the compound for the dopant that produces white color may be obtained by mixing a blue dopant compound and a yellow dopant compound with each other, or by mixing a red dopant compound, a green dopant compound, and a blue dopant compound together.

In an embodiment, Firpic (bis(fluorophenylpyridine)iridium picolinate) is used as the blue dopant compound although not limited thereto, and Irpq2acac (bis(phenylquinoline) iridium acetylacetonate) is used as the yellow dopant compound although not limited thereto.

In one embodiment, Ir(piq)2acac (bis(phenylisoquinoline) iridium acetylacetonate) is used as the red dopant compound although not limited thereto, Irppy3 (tris(phenylpyridine)iridium) is used as the green dopant compound although not limited thereto, and FIrpic(bis(fluorophenylridine) iridium picolinate) is used as the blue dopant compound although not limited thereto.

In an embodiment, 3 to 30 wt % blue dopant compound and 1 to 20 wt % yellow dopant compound with respect to the total weight of the compounds for the host are mixed together to obtain the white color.

In another embodiment, 1 to 20 wt % red dopant compound, 2 to 20 wt % green dopant compound, and 3 to 30 wt % blue dopant compound with respect to the total weight of the compounds for the host are mixed together to obtain a white color.

In one embodiment, the thickness of the emission layer is 20 to 60 nm. When the thickness of the emission layer is smaller than 20 nm, the efficiency of the white OLED deteriorates and the life of the white OLED is reduced. When the thickness of the emission layer is larger than 60 nm, driving voltage increases.

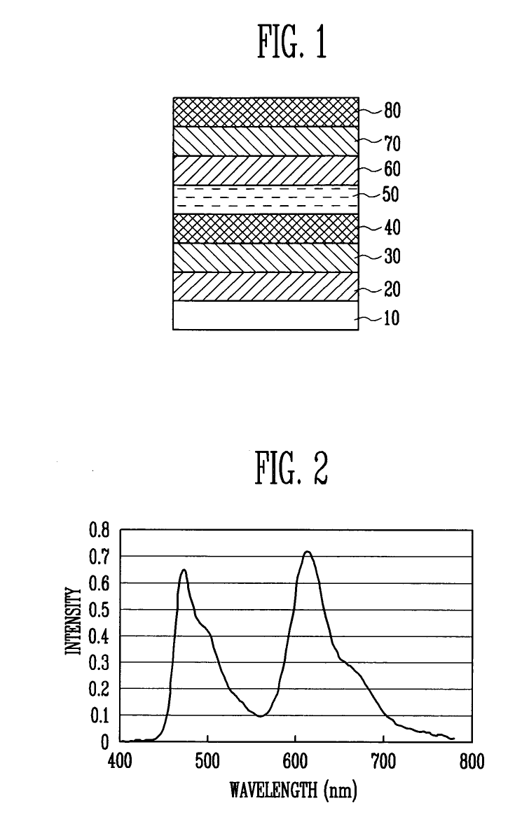

FIG. 1 schematically illustrates the stacked structure of the white OLED according to one embodiment of the invention.

Referring to FIG. 1 which illustrates one embodiment, a first electrode 20 is stacked on a substrate 10, and a hole injecting layer 30, a hole transporting layer 40, an emission layer 50, an electron transporting layer 60, an electron injecting layer 70, and a second electrode 80 are sequentially stacked on the first electrode 20.

In another embodiment not shown in the drawing, a hole blocking layer may be further stacked between the emission layer and the electron transporting layer. In a further embodiment, the hole injecting layer, the hole transporting layer, the electron transporting layer, or the electron injecting layer may be selectively omitted. In a further embodiment, an intermediate layer for improving the interlayer interface characteristics may be further formed.

Hereinafter, an embodiment for a method of manufacturing the white OLED according to the invention will be described with reference to the white OLED having the stacked structure illustrated in FIG. 1 for convenience sake.

First, the patterned first electrode 20 is formed on the substrate 10. In an embodiment, a substrate used for a common OLED such as a glass substrate or a transparent plastic substrate with excellent transparency, surface flatness, ease of handling and water-proof properties is used as the substrate 10, and the thickness of the substrate is 0.3 to 1.1 mm.

In one embodiment, the first electrode 20 is formed of conductive metal or metal oxides into which holes can be easily injected such as indium tin oxide (ITO), indium zinc oxide (IZO), nickel (Ni), platinum (Pt), gold (Au), and iridium (Ir).

In another embodiment, after cleaning the substrate on which the first electrode 20 is formed, UV/ozone processing is performed, at which time organic solvents such as isopropanol (IPA), acetone and so on are used. In an embodiment, the cleaned ITO substrate is plasma processed under vacuum.

In one embodiment, the hole injecting material may be vacuum thermal deposited or spin coated on the first electrode 20 of the cleaned substrate 10 to form the hole injecting layer 30. When the hole injecting layer 30 is formed as described above, the contact resistance between the first electrode 20 and the emission layer 50 is reduced and the hole transporting property of the first electrode 20 with respect to the emission layer 50 is improved such that the driving voltage of the OLED is reduced, and the life of the OLED is increased.

In an embodiment, the thickness of the hole injecting layer 30 is from 300 to 1,500 Å. When the thickness of the hole injecting layer 30 is smaller than 300 Å, the life of the OLED is reduced, the reliability of an organic electroluminescence (EL) device deteriorates, and, in particular, a passive matrix (PM) organic EL may generate a pixel short. When the thickness of the hole injecting layer 30 is larger than 1,500 Å, the driving voltage increases.

In an embodiment, copper phthalocyanine (CuPc) or a starburst amine such as TCTA, m-MTDATA, and IDE406 available from Idemitsu Co. LTD, may be used as the hole injecting material although not limited thereto.

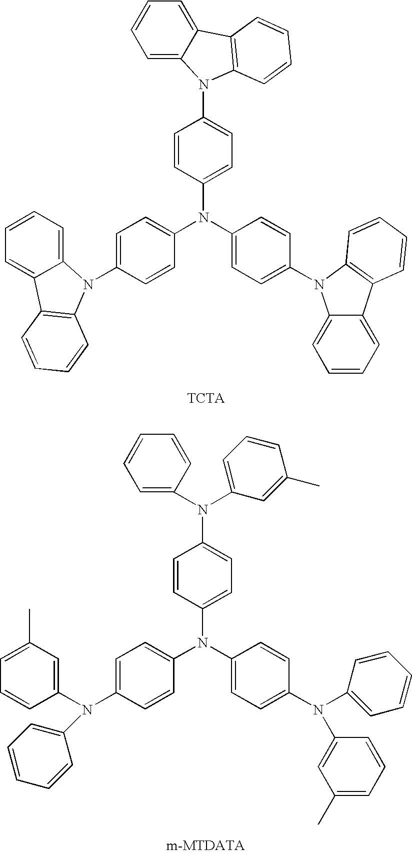

In one embodiment, the hole transporting material may be vacuum thermal deposited or spin coated on the hole injecting layer 30 to form the hole transporting layer 40 from N,N′-bis(3-methylphenyl)-N,N′-diphenyl-[1,1-biphenyl]-4,4′diamine(TPD), N,N′-di(naphthalene-1-yl)-N,N′-diphenyl benzidine, N,N′-di(naphthalene-1-yl)-N,N′-diphenyl-benzidine:α-NPD), IDE320 available from Idemitsu Co. LTD, although not limited thereto.

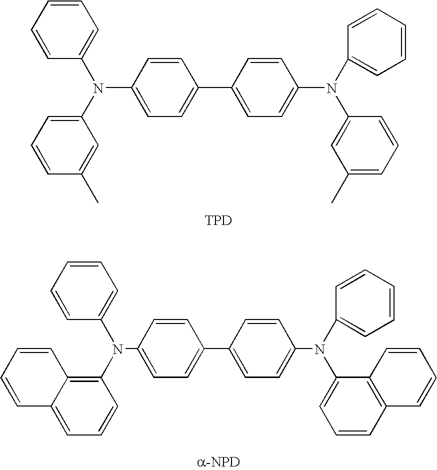

In an embodiment, the thickness of the hole transporting layer is 100 to 400 Å. When the thickness of the hole transporting layer is smaller than 100 Å, the hole transporting property deteriorates. When the thickness of the hole transporting layer is larger than 400 Å, the driving voltage increases.

In an embodiment, the emission layer 50 is formed on the hole transporting layer 40 by vacuum thermal deposition or spin coating.

In one embodiment, in the emission layer 50, two or more kinds of compounds for the host may be used as the host, where at least one material has the hole transporting properties, and the other has the electron transporting properties.

In an embodiment, the materials including a carbazole unit may be used as the hole transporting material, and may be at least one selected from the group consisting of 1,3,5-triscarbazolylbenzene; 4,4′-biscarbazolylbiphenyl; polyvinylcarbazole; m-biscarbazolylbiphenyl; 4,4′-biscarbazolyl-2,2′-dimethylbiphenyl; 4,4′,4″-tri(N-carbazolyl)triphenylamine; 1,3,5-tris(2-carbazolylphenyl)benzene; 1,3,5-tris(2-carbazolyl-5-methoxyphenyl)benzene; bi(4-carbazolylphenyl)silane, and combinations thereof. In an additional embodiment, the organic metal based materials such as aluminum, zinc, beryllium, and potassium based materials, materials including oxadiazol units, materials including triazine units, materials including triazol units, and materials including spiro fluorene units may be used as the electron transporting material. In one embodiment, at least one material is selected from the group consisting of bis(8-hydroxyquinolato)biphenoxy aluminum; bis(8-hydroxyquinolato)phenoxy aluminum; bis(2-methyl-8-hydroxyquinolato)biphenoxy aluminum; bis(2-methyl-8-hydroxyquinolato)phenoxy aluminum; bis(2-(2-hydroxyphenyl)quinolato)zinc; 2-(4-biphenylyl)-5-(4-tert-butylphenyl)-1,3,4-oxadiazol; 2,9-dimethyl-4,7-diphenyl-1,10-phenanthroline(BCP); 2,4,6-tris(diarylamino)-1,3,5-triazine; 3-phenyl-4-(1′-naphthyl)-5-phenyl-1,2,4-triazole, and combinations thereof.

In an embodiment, the hole transporting material is provided in an amount from 10 to 90 wt % with respect to the total weight of the compounds for the host, and the electron transporting material is provided in an amount from 10 to 90 wt % with respect to the total weight of the compounds for the host.

In one embodiment, the white color of the emission layer 50 is realized by mixing the blue dopant compound and the yellow dopant compound with each other, or by mixing the red dopant compound, the green dopant compound, and the blue dopant compound with each other. In an embodiment, FIrpic is used as the blue dopant compound, Irpq2acac is used as the yellow dopant compound, Ir(piq)2acac is used as the red dopant compound, and Irppy3 is used as the green dopant compound.

In a further embodiment, 3 to 30 wt % blue dopant compound, and 1 to 20 wt % yellow dopant compound with respect to the total weight of the compounds for the host are mixed together.

In one embodiment, 1 to 20 wt % red dopant compound, 2 to 20 wt % green dopant compound, and 3 to 30 wt % blue dopant compound with respect to the total weight of the compounds for the host are mixed together.

Although not shown in FIG. 1, in an embodiment, the hole blocking material may be vacuum deposited or spin coated on the emission layer 50 to optionally form the hole blocking layer. At this time, in one embodiment, the hole blocking material must have an ionization potential higher than the ionization potential of the emission compound, while having the electron transporting properties. In an embodiment, Balq, BCP, and TPBI are used as the hole blocking material, and the thickness of the hole blocking layer is 30 to 70 Å. When the thickness of the hole blocking layer is smaller than 30 Å, the hole blocking properties are not well realized. When the thickness of the hole blocking layer is larger than 70 Å, the driving voltage increases.

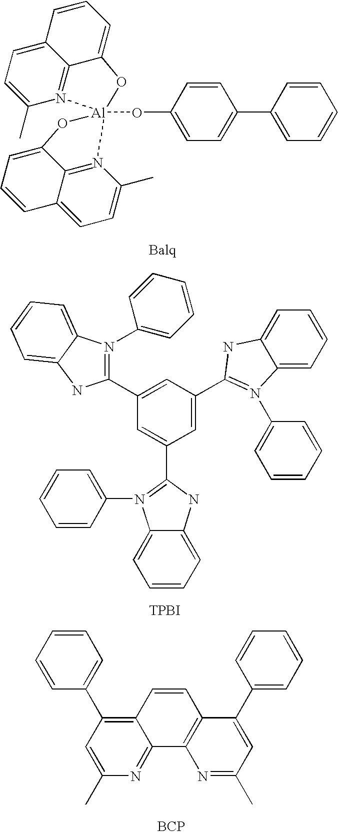

In an embodiment, the electron transporting material is vacuum deposited or spin coated on the emission layer 50 or the hole blocking layer to form the electron transporting layer 60. In a further embodiment, Alq3 may be used as the electron transporting material although not particularly limited thereto.

In one embodiment, the thickness of the electron transporting layer 60 is 150 to 600 Å. When the thickness of the electron transporting layer 60 is smaller than 150 Å, the electron transporting property deteriorates. When the thickness of the electron transporting layer 60 is larger than 600 Å, the driving voltage increases.

In a further embodiment, the electron injecting layer 70 may be stacked on the electron transporting layer 60, and the electron injecting layer 70 may be formed of LiF, NaCl, CsF, Li₂O, BaO, Liq and so on. In one embodiment, the thickness of the electron injecting layer 70 is 5 to 20 Å. When the thickness of the electron injecting layer 70 is smaller than 5 Å, the electron injecting layer 70 does not effectively operate. When the thickness of the electron injecting layer 70 is larger than 20 Å, the driving voltage increases.

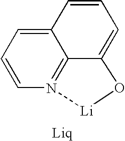

In one embodiment, metal for a cathode that is the second electrode 80 is vacuum thermal deposited on the electron injecting layer 70 to form the cathode that is the second electrode 80, thereby completing a white OLED.

In an embodiment, Li, Mg, Al, Al—Li, Ca, Mg—In, and Mg—Ag are used as the cathode metal.

Hereinafter, the invention will be described with reference to the following examples; however, the invention is not limited to the examples.

### EXAMPLE 1

An ITO glass substrate of 15 Ω/cm² (1,200 Å) obtained from Corning Inc. is cut to a size of 50 mm×50 mm×0.7 mm and is ultrasonically cleaned under a solution of isopropyl alcohol and pure water for 5 minutes and then is UV and ozone cleaned for 30 minutes. After the cleaning process, the ITO glass substrate is plasma processed under a vacuum of no more than 0.1 mtorr for 9 minutes.

IDE406 from Idemitsu Co., LTD is vacuum thermal deposited on the substrate to form the hole injecting layer with a thickness of 700 Å. Then, α-NPD is vacuum thermal deposited on the hole injecting layer with a thickness of 150 Å to form the hole transporting layer.

A 1:1 mixture of CBP(4,4′-biscarbazolylbiphenyl) and BCP(2,9-dimethyl-4,7-diphenyl-9,10-phenanthroline) as the host is doped with 15 wt % FIrpic as the blue dopant and 3 wt % Irqp2acac as the yellow dopant to form a 400 Å thick emission layer on the hole transporting layer by vacuum thermal deposition.

Then Alq3, which is the electron transporting material, is deposited on the emission layer to form the electron transporting layer with a thickness of 250 Å, and LiF at 10 Å thick (the electron injecting layer) and Al at 800 Å thick (the cathode) are sequentially vacuum thermal deposited on the electron transporting layer to form a LiF/Al electrode, thereby manufacturing an OLED.

### EXAMPLE 2

An ITO glass substrate of 15 Ω/cm² (1,200 Å) obtained from Corning Inc. is cut to a size of 50 mm×50 mm×0.7 mm and is ultrasonically cleaned under a solution of isopropyl alcohol and pure water for 5 minutes and then is UV and ozone cleaned for 30 minutes. After the cleaning process, the ITO glass substrate is plasma processed under a vacuum of no more than 0.1 mtorr for 9 minutes.

IDE406 from Idemitsu Co., LTD is vacuum thermal deposited on the substrate to form the hole injecting layer with a thickness of 700 Å. Then, α-NPD is vacuum thermal deposited on the hole injecting layer with a thickness of 150 Å to form the hole transporting layer.

A 1:1 mixture of CBP and BCP as the host is doped with 2 wt % Ir(piq)2acac as the red dopant, 3 wt % Irppy3 as the green dopant, and 15 wt % FIrpic as the blue dopant to form a 400 Å thick emission layer on the hole transporting layer by vacuum thermal deposition.

Then Alq3, which is the electron transporting material, is deposited on the emission layer to form the electron transporting layer with a thickness of 250 Å, and LiF at 10 Å thick (the electron injecting layer) and Al at 800 Å thick (the cathode) are sequentially vacuum thermal deposited on the electron transporting layer to form a LiF/Al electrode, thereby manufacturing an OLED.

### COMPARATIVE EXAMPLE 1

An ITO glass substrate of 15 Ω/cm² (1,200 Å) obtained from Corning Inc. is cut to a size of 50 mm×50 mm×0.7 mm and is ultrasonically cleaned under a solution of isopropyl alcohol and pure water for 5 minutes and then is UV and ozone cleaned for 30 minutes. After the cleaning process, the ITO glass substrate is plasma processed under a vacuum of no more than 0.1 mtorr for 9 minutes.

IDE406 from Idemitsu Co., LTD is vacuum thermal deposited on the substrate to form the hole injecting layer with a thickness of 700 Å. Then, α-NPD is vacuum thermal deposited on the hole injecting layer with a thickness of 150 Å to form the hole transporting layer.

CBP as the host is doped with 15 wt % FIrpic as the blue dopant and 3 wt % Irqp2acac as the yellow dopant to form a 400 Å thick emission layer on the hole transporting layer by vacuum thermal deposition.

Then Alq3, which is the electron transporting material, is deposited on the emission layer to form the electron transporting layer with a thickness of 250 Å, and LiF at 10 Å thick (the electron injecting layer) and Al at 800 Å thick (the cathode) are sequentially vacuum thermal deposited on the electron transporting layer to form a LiF/Al electrode, thereby manufacturing an OLED.

### COMPARATIVE EXAMPLE 2

An ITO glass substrate of 15 Ω/cm² (1,200 Å) obtained from Corning Inc. is cut to a size of 50 mm×50 mm×0.7 mm and is ultrasonically cleaned under a solution of isopropyl alcohol and pure water for 5 minutes and then is UV and ozone cleaned for 30 minutes. After the cleaning process, the ITO glass substrate is plasma processed under a vacuum of no more than 0.1 mtorr for 9 minutes.

IDE406 from Idemitsu Co., LTD is vacuum thermal deposited on the substrate to form the hole injecting layer with a thickness of 700 Å. Then, α-NPD is vacuum thermal deposited on the hole injecting layer with a thickness of 150 Å to form the hole transporting layer.

CBP as the host is doped with 2 wt % Ir(piq)2acac as the red dopant, 3 wt % Irppy3 as the green dopant, and 15 wt % FIrpic as the blue dopant to form a 400 Å thick emission layer on the hole transporting layer by vacuum thermal deposition.

Then Alq3, which is the electron transporting material, is deposited on the emission layer to form the electron transporting layer with a thickness of 250 Å, and LiF at 10 Å thick (the electron injecting layer) and Al at 800 Å thick (the cathode) are sequentially vacuum thermal deposited on the electron transporting layer to form a LiF/Al electrode, thereby manufacturing an OLED.

### EXPERIMENTAL EXAMPLE 1

The driving voltage, efficiency (current density), and half life of the white OLEDs manufactured in accordance with the Examples 1 and 2 and the Comparative Examples 1 and 2 were examined by the following methods and the results are described in Table 1.

Brightness was measured by a BM5A (Topcon).

Driving voltage was measured by a 238 HIGH CURRENT SOURCE MEASURE UNIT from Keithley.

Current density was measured by increasing DC from 10 to 100 mA/cm² by 10 mA/cm² increments, and was measured at no less than 9 points in the same OLED.

Half life was measured by investigating the time required to reduce the brightness of each of the OLEDs to 50% of the initial value when the same current density of DC 50 mA/cm² is applied. Reproducibility of half life was confirmed by three or more OLEDs having the same structure.

Chromaticity coordinate was confirmed by PR650 spectrometer.

TABLE 1

| | Driving | Efficiency | | Chromaticity |
|---|---|---|---|---|
| | voltage (V) | (cd/v) | Half life (h) | (CIEx CIEy) |
| Example 1 | 6.1 | 23 | 400 | 0.31, 0.36 |
| Example 2 | 6.2 | 19 | 600 | 0.30, 0.37 |
| Comparative | 7.3 | 16 | 130 | 0.31, 0.35 |
| Example 1 | | | | |
| Comparative | 7.5 | 13 | 150 | 0.30, 0.36 |
| Example 2 | | | | |

It is noted from Table 1 that the efficiency and half life of the OLEDs of Examples 1 and 2 are larger and longer than the efficiency and half life of the OLEDs of Comparative Examples 1 and 2.

### EXPERIMENTAL EXAMPLE 2

The emission characteristics of the OLED manufactured by Example 1 were investigated and the results are described in the graph illustrated in FIG. 2.

According to a white OLED of the invention, at least one of the hole transporting materials and at least one of the electron transporting materials are used as the host materials of the emission layer to improve the stability of the OLED, and to increase the efficiency and life of the OLED.

What is claimed is:

1. A white organic light emitting diode comprising an emission layer between two electrodes,
wherein the emission layer comprises a host with two or more host compounds and a dopant with two or more dopant compounds that facilitate a white color, and
wherein, at least one host compound is a hole transporting material and at least one host compound is an electron transporting material.

2. The white organic light emitting diode in claim 1, wherein the hole transporting material is present in an amount from 10 to 90 wt % with respect to the total weight of the host compounds.

3. The white organic light emitting diode in claim 1, wherein the electron transporting material is present in an amount from 10 to 90 wt % with respect to the total weight of the compounds for the host.

4. The white organic light emitting diode in claim 1, wherein the hole transporting material is selected from the group consisting of 1,3,5-triscarbazolylbenzene; 4,4′-biscarbazolylbiphenyl; polyvinylcarbazole; m-biscarbazolybilphenyl; 4,4′-biscarbazolyl-2,2′-dimethylbiphenyl; 4,4′,4″-tri(N-carbazolyl)triphenylamine; 1,3,5-tris(2-carbazolylphenyl)benzene; 1,3,5-tris(2-carbazolyl-5-methoxyphenyl)benzene; bi(4-carbazolylphenyl)silane, and combinations thereof.

5. The white organic light emitting diode in claim 1, wherein the electron transporting material is selected from the group consisting of bis(8-hydroxyquinolato)biphenoxy aluminum; bis(8-hydroxyquinolato)phenoxy aluminum; bis(2-methyl-8-hydroxyquinolato)biphenoxy aluminum; bis(2-methyl-8-hydroxyquinolato)phenoxy aluminum; bis(2-(2-hydroxyphenyl)quinolato)zinc; 2-(4-biphenylyl)-5-(4-tert-butylphenyl)-1,3,4-oxadiazol; 2,9-dimethyl-4,7-diphenyl-1,10-phenanthroline(BCP); 2,4,6-tris(diarylamino)-1,3,5-triazine; 3-phenyl-4-(1′-naphthyl)-5-phenyl-1,2,4-triazole, and combinations thereof.

6. The white organic light emitting diode in claim 1, wherein the dopant compound is a mixture of a blue dopant compound and a yellow dopant compound.

7. The white organic light emitting diode in claim 1, wherein the dopant compound is a mixture of a red dopant compound, a green dopant compound, and a blue dopant compound.

8. The white organic light emitting diode in claim 6,
wherein FIrpic is used as the blue dopant compound, and Irpq2acac is used as the yellow dopant compound.

9. The white organic light emitting diode in claim 7,
wherein Ir(piq)2acac is used as the red dopant compound,
Irppy3 is used as the green dopant compound, and
FIrpic is used as the blue dopant compound.

10. The white organic light emitting diode in claim 6,
wherein the mixture comprises from 3 to 30 wt % blue dopant compound, and from 1 to 20 wt % yellow dopant compound with respect to the total weight of the host compounds.

11. The white organic light emitting diode in claim 7,
wherein the mixture comprises from 1 to 20 wt % red dopant compound,
from 2 to 20 wt % green dopant compound, and
from 3 to 30 wt % blue dopant compound with respect to the total weight of the host compounds.

12. The white organic light emitting diode in claim 1, wherein the thickness of the emission layer is from 20 to 60 nm.
